(19) United States
(12) Patent Application Publication
(10) Pub. No.: US 2008/0188054 A1
(43) Pub. Date: Aug. 7, 2008

(54) FABRICATING RESISTORS

(75) Inventors: Jong Min KIM, Seoul (KR); San Hong Kim, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/829,622

(22) Filed: Jul. 27, 2007

(30) Foreign Application Priority Data
Jul. 27, 2006 (KR) 10-2006-0070517

(51) Int. Cl. H01L 21/02; B05C 11/00

(52) U.S. Cl. 438/382; 118/504; 257/E21.004

(57) ABSTRACT

Methods for fabricating polysilicon resistors or silicon diffused resistors and mask structures for use in said methods. In one example embodiment, a method of fabricating a resistor includes forming an insulating layer on a semiconductor substrate, forming a polysilicon pattern on the insulating layer, and implanting impurity on the polysilicon pattern through an impurity implantation mask. The mask includes one or more blocking patterns at a predetermined interval in a first direction. Each blocking pattern has a length in a second direction that is substantially orthogonal to the first direction. The length is longer than a width of the polysilicon pattern in the second direction.

### CROSS-REFERENCE TO RELATED APPLICATION

This application claims priority to Korean Application No. 10-2006-0070517, filed on Jul. 27, 2006, which is incorporated herein by reference in its entirety.

### BACKGROUND

1. Field of the Invention

The invention relates to fabricating resistors, and more particularly, to fabricating polysilicon resistors or silicon diffused resistors.

2. Description of the Related Art

In general, an N-type or a P-type source/drain impurity ion implantation is used to fabricate a polysilicon resistor. FIGS. 1A to 1C disclose a conventional method for fabricating a strip type polysilicon resistor. FIG. 1A discloses a polysilicon resistor before having a mask for source/drain impurity ion implantation formed thereon. FIG. 1B discloses the polysilicon resistor of FIG. 1A after having a mask for source/drain impurity ion implantation formed thereon. FIG. 1C discloses the polysilicon resistor of FIG. 1B after having been subjected to an impurity ion implantation.

With reference first to FIG. 1A, a polysilicon pattern including regions 4, 5 and 6 is formed on a substrate 2. The region 6 of the polysilicon pattern is configured to be subjected to an impurity implantation during the formation of the polysilicon resistor. Although not shown in FIG. 1A, an insulating layer can be formed on the substrate 2 before the polysilicon pattern is deposited on the substrate 2.

With reference now to FIG. 1B, an impurity implantation mask 10 for source/drain impurity implantation is disposed on the substrate 2. The mask 10 is divided into an opened region 12 and a blocked region 14. The polysilicon resistor is fabricated by implanting an impurity through the opened region 12 of the mask 10, resulting in the polysilicon resistor having a predetermined sheet resistance. The impurity, which may be a P-type or an N-type impurity, is employed to control the resistance of the polysilicon resistor.

With reference now to FIG. 1C, after the impurity is implanted, the mask 10 is removed and contact holes 8 are then formed by conventional post processes.

If the capacity to fabricate another polysilicon resistor having a different sheet resistance becomes necessary, a new mask is required because a doping level of an impurity implanted in the source/drain is fixed to a condition for a NMOS or a PMOS device. Also, additional processes may be required in order to form another polysilicon resistor having another sheet resistance because the conventional method disclosed in FIGS. 1A to 1C for allows only one type of the polysilicon resistor to be fabricated. Similar problems arise when a silicon-diffused resistor is fabricated in silicon.

### SUMMARY OF SOME EXAMPLE EMBODIMENTS

In general, example embodiments of the invention relate to fabricating resistors having various sheet resistance values. In one example embodiment, a method for fabricating resistors can employ a single mask for fabricating resistors having various sheet resistance values.

In one example embodiment of the invention, a method of fabricating a resistor includes forming an insulating layer on a semiconductor substrate, forming a polysilicon pattern on the insulating layer, and implanting impurity on the polysilicon pattern through an impurity implantation mask. The mask includes one or more blocking patterns at a predetermined interval in a first direction. Each blocking pattern includes a length in a second direction that is substantially orthogonal to the first direction. The length in the second direction is longer than a width of the polysilicon pattern in the second direction.

In another example embodiment of the invention, a method of fabricating a resistor includes forming an insulating layer on a semiconductor substrate, forming a polysilicon pattern on the insulating layer, and implanting impurity on the polysilicon pattern through an impurity implantation mask. The mask includes a plurality of blocking patterns formed on a region for implanting impurity within the polysilicon pattern.

In yet another example embodiment of the invention, a mask structure for use in fabricating a resistor by impurity implantation on a polysilicon pattern through the mask includes a plurality of blocking patterns arranged in a textile fashion on a region for implanting the impurity within the polysilicon pattern.

In another example embodiment of the invention, a method of fabricating a resistor includes forming an insulating layer on a semiconductor substrate, forming a polysilicon pattern on the insulating layer, and implanting impurity on the polysilicon pattern through an impurity implantation mask. The mask includes a plurality of blocking patterns through which the impurity is implanted onto the polysilicon pattern.

### BRIEF DESCRIPTION OF THE DRAWINGS

Aspects of example embodiments of the invention will become apparent from the following description of example embodiments given in conjunction with the accompanying drawings, in which:

FIG. 1A is a schematic diagram of a polysilicon resistor before having a mask for source/drain impurity ion implantation formed thereon;

FIG. 1B is a schematic diagram of the polysilicon resistor of FIG. 1A after having a mask for source/drain impurity ion implantation formed thereon;

FIG. 1C is a schematic diagram of the polysilicon resistor of FIG. 1B after having been subjected to an impurity ion implantation;

FIG. 2A is a diagram of a first example method for fabricating a resistor;

FIG. 2B is a graph schematically showing a resistance level that can be achieved by the example method of FIG. 2A;

FIG. 3A is a diagram disclosing an second example method for fabricating a resistor;

FIG. 3B is a graph schematically showing a resistance level that can be achieved by the example method of FIG. 3A; and

FIG. 4 is a diagram disclosing a third example method for fabricating a resistor.

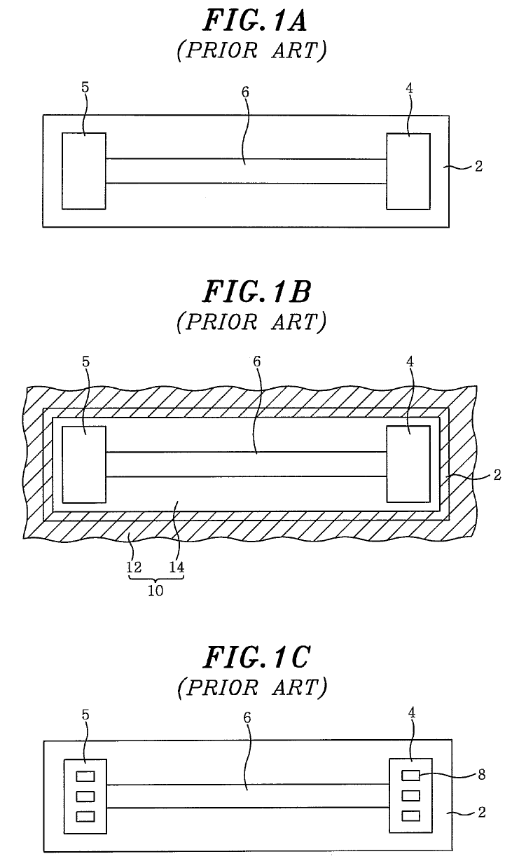

### DETAILED DESCRIPTION OF SOME EXAMPLE EMBODIMENTS

Hereinafter, aspects of example embodiments of the invention will be described with reference to the accompanying drawings.

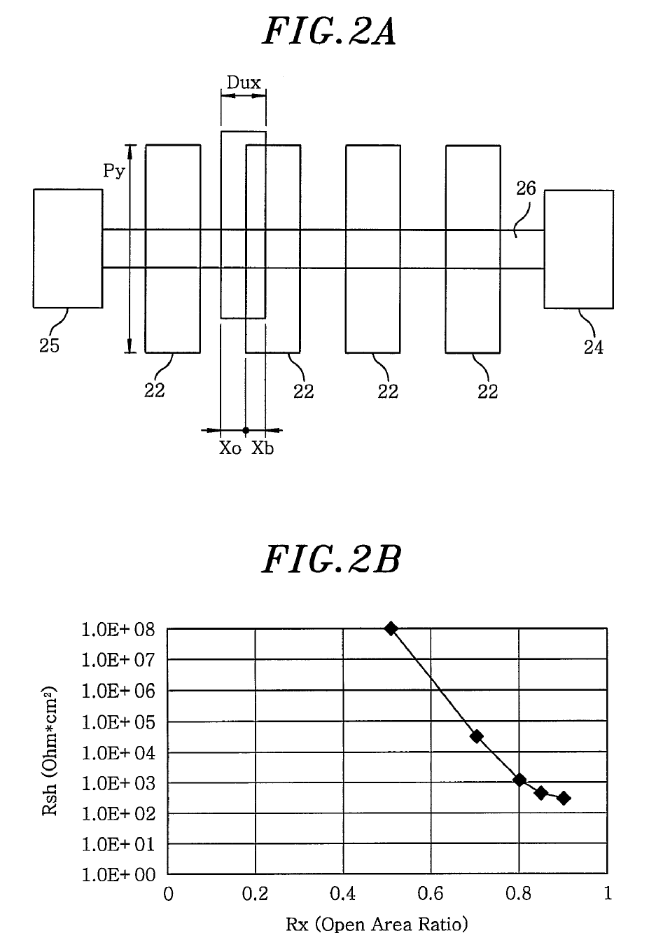

FIG. 2A discloses a first example method for fabricating a resistor. The method disclosed in FIG. 2A includes forming an insulating layer on an N-type or P-type semiconductor substrate, forming a polysilicon pattern on the insulating layer, and implanting impurity on the polysilicon pattern through an impurity implantation mask. The mask has a predetermined length in a first direction. The length is longer than a width of the polysilicon pattern in the first direction. The mask includes one or more blocking patterns at a predetermined interval in a second direction. The second direction is substantially orthogonal to the first direction.

Although the forming of the insulating layer and the forming of the polysilicon pattern are not shown in FIG. 2A, the implanting of the impurity will now be described with reference to FIG. 2A. First, an impurity implantation mask is formed on a substrate (not shown) having a polysilicon pattern including regions 24, 25 and 26. The mask includes one or more blocking patterns 22 disposed at a predetermined interval in a first direction. Each of the blocking patterns 22 has a length Py in a second direction that is substantially orthogonal to the first direction. The length Py is longer than a width of the polysilicon pattern 24, 25 and 26 in the second direction.

As disclosed in FIG. 2A, the first direction is the direction of a current flow that is an X-axis direction, and the second direction is a Y-axis direction that is substantially orthogonal to the first direction.

A strip polysilicon resistor is formed by impurity implantation through the mask. A sheet resistance of the polysilicon resistor may be determined by an amount of impurity implanted into the polysilicon pattern. The impurity may be a P-type or an N-type impurity.

Accordingly, if a region for implanting the impurity on the polysilicon pattern is controlled using the mask of FIG. 2A, a total amount of impurity to be implanted into the polysilicon region can be controlled without changing the mask of FIG. 2A. Two parameters of the polysilicon resistor can be used to control the amount of impurity, namely, a minimum design rule Dr and a lateral diffusion length Dd. The minimum design rule Dr denotes a rule for patterning the mask, and the lateral diffusion length Dd denotes a length of implanted impurity diffused laterally in polysilicon. The two factors Dr and Dd can be controlled during the fabricating process of the polysilicon resistor.

Mask design parameters can also be defined by the two factors Dr and Dd. These mask design parameters include a unit length Dux, an opening length Xo, and a blocking length Xb. The opening length Xo can be equal to or longer than Dr/2 (X0≧Dr/2), and the blocking length Xb can be equal to or shorter than Dd and equal to or longer than Dr/2 (Dd≧Xb≧Dr/2). The unit length Dux is the sum of the opening length Xo and the blocking length Xb (i.e., Dux=Xo+Xb).

If the blocking length Xb is 0, the polysilicon pattern is entirely opened. Also, the blocking length Xb may be defined with relation to the lateral diffusion length Dd because diffusion can be made from both sides of the polysilicon pattern. The lateral diffusion length Dd is generally longer than the minimum design rule Dr because the diffusivity of the impurity is large in polysilicon. Accordingly, it is possible to determine an open area ratio Rx between the blocking region and the opened region. The area ratio Rx can be expressed by:

Rx=Xo/(Xo+Xb)=1/(1+Xb/Xo) (Equation 1)

In Equation 1, the maximum value of the area ratio Rx is 1 where Xb=0, the minimum value of the area ratio Rx1 is about 1/(1+2*Dd/Dr). For example, the area ratio Rx can be reduced up to about 0.25 if it is assumed that Dd=0.3 μm and Dr=0.18 μm˜0.20 μm.

A resistor fabricated using the mask having the blocking pattern shown in FIG. 2A will have serial resistance characteristics. FIG. 2B discloses a resistance level that can be achieved by the first example method of FIG. 2A. Due to the resistance characteristics of the polysilicon, resistance can vary abruptly. Also, mobility of the polysilicon becomes abruptly lowered as a doping level is lowered. As a result, the resistance increases by geometric progression.

With continuing reference to FIG. 2B, the sheet resistance Rsh of the resistor is reduced by geometric progression when the area ratio Rx becomes closer to 1, that is, when the doping level becomes increased. Also, as disclosed in FIG. 2B, when the area ratio Rx is about 0.5, the sheet resistance Rsh of the resistor increases by geometric progression.

As described above, the first example method of fabricating a resistor disclosed in FIG. 2A can minimize additional processes when the need arises to fabricate resistors having different sheet resistance values. Therefore, resistors having various sheet resistance values can be fabricated using the first example fabricating method disclosed in FIG. 2A.

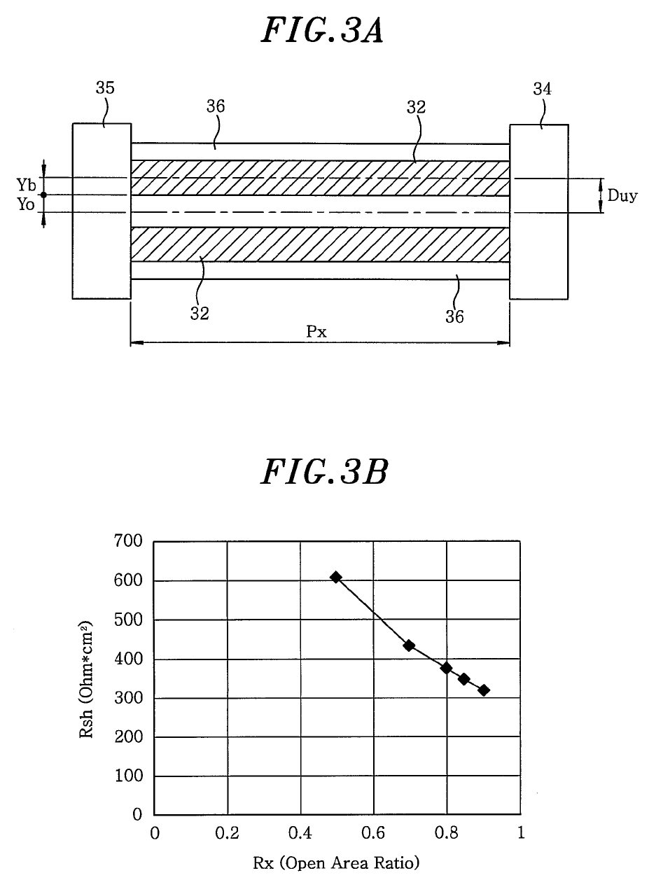

With reference now to FIGS. 3A and 3B, a second example method for fabricating a resistor is disclosed. FIG. 3A discloses the second example method for fabricating a resistor, and FIG. 3B discloses a resistance level that can be achieved by the second example method.

FIG. 3A discloses an example impurity implantation mask that is formed on a substrate (not shown) having a polysilicon pattern including regions 34, 35 and 36. The example mask includes one or more blocking patterns 32 disposed at a predetermined interval in a second direction. Each of the blocking patterns 32 has a length Px in a first direction which is longer than a width of the polysilicon pattern 34, 35 and 36 in the second direction. In this regard, the first direction is the direction of a current flow that is an X-axis direction, and the second direction is a Y-axis direction that is substantially orthogonal to the first direction.

Similar design concepts disclosed in FIG. 2A can be applied to the example mask disclosed in FIG. 3A. In particular, Yo≧Dr/2, Dd≧Yb≧Dr/2 (or, Yb=0), and Duy=Yo+Yb where Duy denotes a unit width, Yo denotes an opening width, and Yb denotes a blocking width. Therefore, an open area ratio Ry is represented as follow:

Ry=Yo/(Yo+Yb)=1/(1+Yb/Yo) (Equation 2)

As disclosed in FIG. 3B, a resistance level that can be achieved by the example resistor fabricating method of FIG. 3A is about 600Ω when the area ratio Ry of the open region is about 0.5 because the sheet resistance value Rsh is gradually reduced as the area ratio Ry approaches 1.

As described above, the second example method of fabricating a resistor disclosed in FIG. 3A can minimize additional processes when the need arises to fabricate resistors having different sheet resistances. Therefore, resistors having various sheet resistances can be fabricated using the example fabricating method disclosed in FIG. 3A.

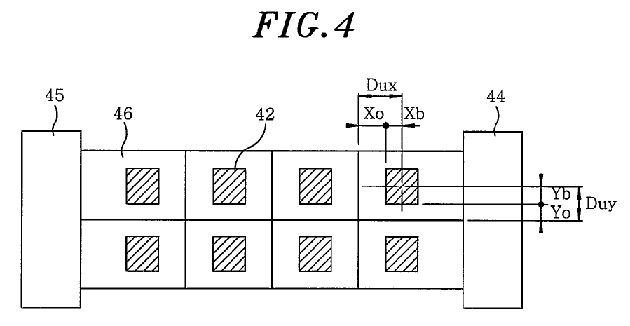

FIG. 4 is a diagram disclosing a third example embodiment of a method for fabricating a resistor. The third example resistor fabricating method of FIG. 4 includes forming an insulating layer on an N-type or a P-type semiconductor substrate, forming a polysilicon pattern on the insulating layer, and implanting impurity using a mask having a plurality of blocking patterns having a predetermined area on the polysilicon pattern.

The example method of FIG. 4 differs from those of FIG. 2A and FIG. 3A in the implanting of the impurity. Unlike the blocking patterns formed in one direction at a predetermined interval disclosed in FIG. 2A and FIG. 3A, the example method disclosed in FIG. 4 employs a plurality of blocking patterns 42 arranged in a textile fashion that are formed in both the first and second directions. The blocking patterns 42 are formed on a region 46 for implanting impurity within a polysilicon pattern including regions 44, 45 and 46. More particular, an example impurity implantation mask is disposed on a substrate (not shown) having the polysilicon pattern 44, 45 and 46. The example mask includes the plurality of blocking patterns 42 disposed in a textile fashion at a predetermined interval in first and second directions. Each of the blocking patterns 42 has a length and a width which are shorter than those of the polysilicon pattern 44, 45 and 46 in the first and the second directions.

Similar design concepts disclosed in FIGS. 2A and 3A can be applied to the example mask disclosed in FIG. 4. In particular, Xo≧Dr/2, Dd≧Xb≧Dr/2, Dux=Xo+Xb, Yo≧Dr/2, Dd≧Yb≧Dr/2, Duy=Yo+Yb, and Rx=Xo/(Xo+Xb). Since Ry=Yo/(Yo+Yb), 1/(1+Dr/(2Dux))≧Rx2≧1/(1+2Dd/Dr), and 1/(1+Dr/(2Duy))≧Ry2≧1/(1+2Dd/Dr). Therefore, the open area ratio Rt is expressed as follows:

Rt=1−(1−Rx2)*(1−Ry2) (Equation 3)

For example, if it is assumed that the minimum design rule is about 0.18 μm, then Dux=Duy=1 μm, a source/drain mask has Dd=0.3 μm, and Dr=0.2 μm. The minimum value of Rt is calculated as 1−(1−1/(1+2Dd/Dr))*(1−1/(1+2Dd/Dr)), which results in a value of about 0.4375. In addition, the maximum value is 1 if Xo and Yo increase infinitely. In the case where Xo=Yo and Xb=Yb, Rt=1−(Rx2−1)².

As described above, the third example method of fabricating a resistor disclosed in FIG. 4 can minimize additional processes when the need arises to fabricate resistors having different sheet resistance values. Therefore, resistors having various sheet resistance values can be fabricated using the example fabricating method disclosed in FIG. 4. Also, the third example method of fabricating a resistor can eliminate the need for new masks structures due to a doping level of impurity being fixed at NMOS or PMOS device conditions.

With reference now to FIG. 2A to FIG. 4, aspects of an example mask structure for manufacturing a resistor will be disclosed.

With reference first to FIG. 2A, a first example embodiment of an impurity implantation mask structure will be described. The first example mask structure is formed on a polysilicon pattern including regions 24, 25 and 26. The first example mask structure includes one or more blocking patterns 22 formed along an X-axis. Each of the blocking patterns 22 has a length Py in a Y-axis direction. The length Py is longer than a width of the polysilicon pattern in the Y-axis direction. The Y-axis direction is substantially orthogonal to the X-axis direction.

With reference now to FIG. 3A, a second example impurity implantation mask structure will be described. The second example mask structure is formed on the polysilicon pattern including regions 34, 35 and 36. The second example mask structure has one or more blocking patterns 32 formed along a Y-axis. Each of the blocking patterns 32 has a length Px in an X-axis direction, which is longer than the width of the polysilicon pattern in the Y-axis direction.

With reference now to FIG. 4, a third example impurity implantation mask structure will be described. The third example mask structure is formed on the polysilicon pattern including regions 44, 45, and 46. The third example mask structure includes a plurality of blocking patterns 42, each blocking pattern having an area formed on a region 46.

In addition, the first, second, and third example mask structures each include an opened region, a blocking region, and an open area ratio, as discussed above.

As disclosed herein, the example mask structures are designed in consideration of a minimum design rule and a lateral diffusion length for implanting impurity in an impurity implanting region of polysilicon resistors. Therefore, resistors having various sheet resistance values can be fabricated using the example mask structures disclosed herein.

Further, the example mask structures and the example resistor fabricating methods disclosed herein can eliminate the need to employ new mask structures due to the doping level of impurity implanted in a source/drain being fixed to an NMOS or a PMOS device condition.

While the invention has been shown and described with respect to some example embodiments, it will be understood by those skilled in the art that various changes and modifications may be made without departing from the scope of the invention as defined in the following claims.

What is claimed is:

1. A method of fabricating a resistor comprising:
forming an insulating layer on a semiconductor substrate;
forming a polysilicon pattern on the insulating layer; and
implanting impurity on the polysilicon pattern through an impurity implantation mask, the mask having one or more blocking patterns positioned at a predetermined interval in a first direction, each blocking pattern having a length in a second direction that is substantially orthogonal to the first direction, the length being longer than a width of the polysilicon pattern in the second direction.

2. The method of claim 1, wherein the first direction is an X-axis direction.

3. The method of claim 1, wherein the second direction is a Y-axis direction.

4. A method of fabricating a resistor comprising:
forming an insulating layer on a semiconductor substrate;
forming a polysilicon pattern on the insulating layer; and
implanting impurity on the polysilicon pattern through an impurity implantation mask, the mask having a plurality of blocking patterns formed on a region for implanting impurity within the polysilicon pattern.

5. The method of claim 4, wherein the blocking patterns are arranged in a textile fashion.

6. A mask structure for use in fabricating a resistor by impurity implantation on a polysilicon pattern through the mask, the mask structure comprising:
one or more blocking patterns formed at a predetermined interval in a first direction,
wherein each blocking pattern has a length in a second direction that is substantially orthogonal to the first direction, the length being longer than a width of the polysilicon pattern in the second direction.

7. The mask structure of claim 6, wherein the first direction is an X-axis direction.

8. The mask structure of claim 6, wherein the second direction is a Y-axis direction.
